(19) United States
(12) Patent Application Publication
(10) Pub. No.: US 2022/0223704 A1
(43) Pub. Date: Jul. 14, 2022

(54) SEMICONDUCTOR STRUCTURE AND FORMATION METHOD THEREOF

(71) Applicant: CHANGXIN MEMORY TECHNOLOGIES, INC., Hefei City (CN)

(72) Inventor: Chengfang CHAO, Hefei City (CN)

(73) Assignee: CHANGXIN MEMORY TECHNOLOGIES, INC., Hefei City (CN)

(21) Appl. No.: 17/451,597

(22) Filed: Oct. 20, 2021

Related U.S. Application Data
(63) Continuation of application No. PCT/CN2021/110879, filed on Aug. 5, 2021.

(30) Foreign Application Priority Data
Jan. 8, 2021 (CN) 202110024414.8

(51) Int. Cl. H01L 29/423; H01L 21/762; H01L 21/768

(52) U.S. Cl. CPC H01L 29/4236; H01L 21/76825; H01L 21/76237

(57) ABSTRACT

A semiconductor structure formation method includes: providing a base and a trench located in the base, and depositing a fluidic initial film layer in the trench, impurity elements being present in the initial film layer; performing reactive oxygen treatment on the initial film layer; performing ultraviolet irradiation treatment on the initial film layer; and performing thermal treatment on the initial film layer in an aerobic environment, removing the impurity elements, and converting the initial film layer into a solid film layer. Quality of the film layer of the semiconductor structure can therefore be improved.

### CROSS-REFERENCE TO RELATED APPLICATIONS

This is a continuation of International Patent Application No. PCT/CN2021/110879 filed on Aug. 5, 2021, which claims priority to Chinese Patent Application No. 202110024414.8 filed on Jan. 8, 2021. The above-referenced applications are hereby incorporated by reference in their entirety.

### BACKGROUND

A dynamic random-access memory is a semiconductor memory widely used in multi-computer systems. With constant miniaturization of a feature size of a semiconductor integrated circuit device, a trench in a semiconductor structure has an increasingly-large aspect ratio, which has increasingly-high requirements on a filling process. Existing processes for filling a trench with a relatively-large aspect ratio are mainly a Flowable Chemical Vapor Deposition (FCVD) process and a Spin On Dielectric (SOD) process.

### SUMMARY

Embodiments of the present application relate to the field of semiconductors, and in particular, to a semiconductor structure and a formation method thereof.

According to some embodiments, in a first aspect, the present application provides a semiconductor structure formation method, including: providing a base and a trench located in the base, and depositing a fluidic initial film layer in the trench, impurity elements being present in the initial film layer; performing reactive oxygen treatment on the initial film layer; performing ultraviolet irradiation treatment on the initial film layer; and performing thermal treatment on the initial film layer in an aerobic environment, removing the impurity elements, and converting the initial film layer into a solid film layer.

According to some embodiments, in a second aspect, the present application provides a semiconductor structure, including: a base, the base being provided with a trench; and a film layer filling up the trench, the film layer being formed according to the semiconductor structure formation method in the first aspect of the present application.

### BRIEF DESCRIPTION OF DRAWINGS

One or more embodiments are exemplarily described by using figures that are corresponding thereto in the accompanying drawings; the exemplary descriptions do not constitute limitations on the embodiments. Elements with same reference numerals in the accompanying drawings are similar elements. Unless otherwise particularly stated, the figures in the accompanying drawings do not constitute a scale limitation.

FIG. 1 is a schematic structural diagram of a semiconductor structure;

FIG. 2 is a first schematic structural diagram of a step of a semiconductor structure formation method according to a first embodiment of the present application;

FIG. 3 is a second schematic structural diagram of a step of a semiconductor structure formation method according to the first embodiment of the present application;

FIG. 4 is a third schematic structural diagram of a step of a semiconductor structure formation method according to the first embodiment of the present application;

FIG. 5 is a fourth schematic structural diagram of a step of a semiconductor structure formation method according to the first embodiment of the present application;

FIG. 6 is a fifth schematic structural diagram of a step of a semiconductor structure formation method according to the first embodiment of the present application; and

FIG. 7 is a schematic structural diagram of a semiconductor structure according to a second embodiment of the present application.

### DETAILED DESCRIPTION

Both the FCVD process and the SOD process may involve first depositing a fluidic initial film layer containing impurity elements. Since the trench in the semiconductor structure has a large aspect ratio, when a film layer finally required is formed subsequently through thermal treatment, the initial film layer at a top is converted into a solid film layer before impurities at a bottom of the initial film layer are discharged. As a result, the impurity elements do not escape from the initial film layer, and the film layer formed has the impurity elements.

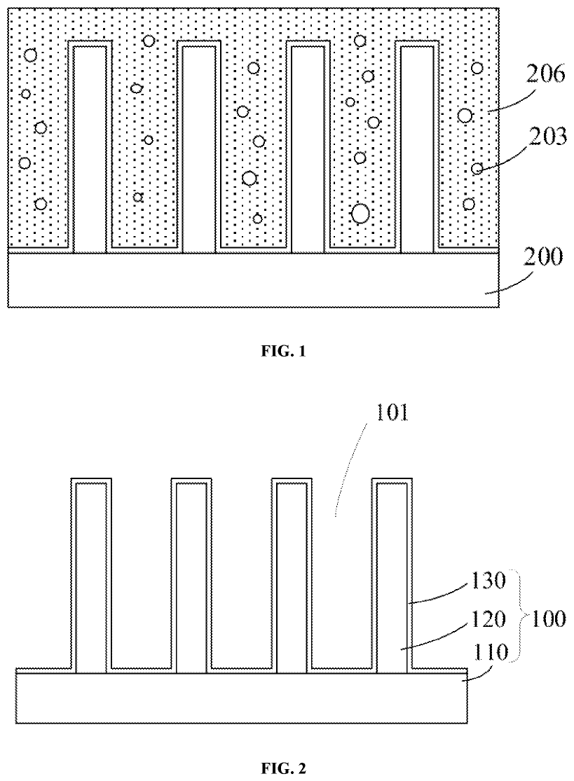

FIG. 1 is a schematic structural diagram of a semiconductor structure.

Referring to FIG. 1, a semiconductor structure includes a base 200 and a film layer 206. The film layer 206 contains impurity elements 203.

The step of forming the film layer 206 involves: depositing a fluidic initial film layer, the initial film layer containing the impurity elements 203; and performing thermal treatment on the initial film layer in an aerobic environment. During the thermal treatment, the impurity elements 203 at a bottom are required to obtain enough energy to escape from the initial film layer. However, when the impurity elements 203 do not obtain enough energy, the initial film layer at a top is cured at a high temperature to form the solid film layer 206. The solid film layer 206 is of a sealed structure, which prevents escape of the impurity elements 203 from the film layer. As a result, the formed film layer 206 of the semiconductor structure contains the impurity elements 203, and the film layer 206 has low quality.

An embodiment of the present application provides a semiconductor structure formation method, in which after an initial film layer is formed, reactive oxygen treatment and ultraviolet irradiation treatment are performed first, and then thermal treatment is performed to form a film layer not containing impurity elements, thereby improving the quality of the film layer.

In order to make the objectives, technical solutions and advantages of the embodiments of the present application clearer, various embodiments of the present application will be described below in detail with reference to the drawings. However, those of ordinary skill in the art may understand that, in the embodiments of the present application, numerous technical details are set forth in order to enable a reader to better understand the present application. However, the technical solutions claimed in the present application can be implemented without these technical details and various changes and modifications based on the embodiments below.

FIG. 2 to FIG. 6 are schematic structural diagrams of steps of a semiconductor structure formation method according to a first embodiment of the present application.

Referring to FIG. 2, the semiconductor structure formation method according to the first embodiment of the present application includes: providing a base 100 and a trench 101 located in the base 100.

The base 100 is of a multilayer structure and includes: a substrate 110, a gate 120 and a diffusion barrier layer 130.

The substrate 110 may be made of sapphire, silicon, silicon carbide, gallium arsenide, aluminum nitride, zinc oxide or the like. In the present embodiment, the substrate 110 is made of a silicon material.

Discrete gates 120 are formed on a surface of the substrate 110. The gate 120 serves as a wordline structure of the semiconductor structure. The gate 120 is made of tungsten. In other embodiments, the gate may also be made of copper, aluminum, gold, silver or the like.

Gases used to form the gate 120 made of tungsten include silane and tungsten hexafluoride. When the gate 120 is formed, a tungsten metal layer manufactured by silane and tungsten hexafluoride has a small grain size, which reduces surface roughness of the gate 120 and improves flatness of a top surface of the gate 120.

The diffusion barrier layer 130 is formed on surfaces of the substrate 110 and the gate 120. The diffusion barrier layer 130 may prevent diffusion of metal particles in the gate 120.

The diffusion barrier layer 130 may be formed by an atomic layer deposition process. The diffusion barrier layer 130 with a uniform thickness can be formed on the discrete gates 120 by the atomic layer deposition process. In other embodiments, the diffusion barrier layer may also be formed by a chemical vapor deposition process.

The diffusion barrier layer 130 may be of a monolayer structure or a multilayer structure. The diffusion barrier layer 130 may be made of a nitride or an oxide, which may specifically be tantalum nitride or titanium nitride.

In the present embodiment, the trench 101 is formed between the discrete gates 120. The trench 101 may be a shallow trench, a capacitor contact trench or a metal wiring trench.

The trench 101 has an aspect ratio of 5:1 to 25:1, which may specifically be 10:1, 15:1 or 20:1. A larger aspect ratio satisfies a requirement of the semiconductor structure for a feature size as small as possible.

In other embodiments, the base may further include: a substrate; a plurality of discrete capacitor contact layers buried in the substrate, the substrate exposing an upper surface of the capacitor contact layer; a plurality of discrete isolation layers sequentially stacked on a surface of the substrate; a plurality of discrete stable layers sequentially stacked on a surface of the isolation layer; and a lower electrode located on the upper surface of the capacitor contact layer, a sidewall of the isolation layer and a sidewall of the stable layer.

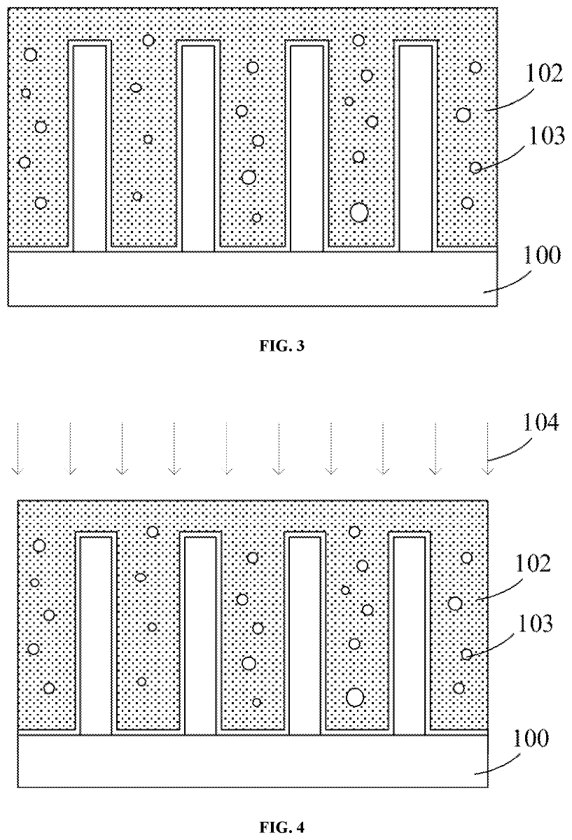

Referring to FIG. 3, in the present embodiment, a fluidic initial film layer 102 is deposited in the trench 101 (referring to FIG. 2). Impurity elements 103 are present in the initial film layer 102.

In the present embodiment, the initial film layer 102 is formed by an SOD process. In the SOD process, firstly, the base 100 is rotated at a certain speed, and a fluidic precursor is provided for the trench 101 at the same time. The precursor is subjected to a centripetal force of rotation in the trench 101, and under the centripetal force, diffuses in all directions to form the uniform fluidic initial film layer 102 filling up the trench 101, which is then sintered in an aerobic environment to form a solid film layer.

When the initial film layer 102 is formed by the SOD process, the formed initial film layer 102 uniformly fills up the entire trench 101 due to the centripetal force of rotation, such that an air gap may not be formed.

In other embodiments, the initial film layer may also be formed by an FCVD process.

In the present embodiment, during the formation of the initial film layer 102 by spin on dielectric in the SOD process, the base 100 is rotated at a rate of 500 revolutions per minute to 3000 revolutions per minute, which may specifically be 1000 revolutions per minute, 1500 revolutions per minute or 2000 revolutions per minute.

The initial film layer 102 may be made of a silicon-containing polymer compound such as silicon nitrogen hydroxide or silicon nitride. When the initial film layer 102 is deposited, due to the presence of nitrogen and hydrogen elements in the deposited precursor, the deposited initial film layer 102 is a silicon nitrogen hydroxide layer.

The impurity elements 103 are a nitrogen element, a hydrogen element and nitrogen-hydrogenated bonding. The initial film layer 102 may be cured subsequently. The impurity elements 103 are required to obtain enough energy to escape from the initial film layer 102 before the initial film layer 102 is converted into the solid film layer.

Referring to FIG. 4, reactive oxygen treatment 104 is performed on the initial film layer 102.

In the present embodiment, the reactive oxygen treatment 104 on the initial film layer 102 involves providing peroxide, superoxide, or ozonide for the initial film layer 102.

The peroxide includes: hydrogen peroxide or singlet oxygen. The superoxide includes: superoxide anions or hydroxyl radicals. The ozonide includes: ozone or ozone anions.

A gas flow of the peroxide, the superoxide, or the ozonide is 1000 sccm to 20000 sccm (standard cubic centimeter per minute), which may specifically be 5000 sccm, 10000 sccm or 15000 sccm.

When a gas flow used for the reactive oxygen treatment 104 is too small, an ultraviolet transmittance of a part of the initial film layer 102 that can be transmitted through by reactive oxygen is not completely increased by the reactive oxygen. The reactive oxygen treatment 104 is intended mainly to increase the ultraviolet transmittance of the initial film layer 102 instead of providing energy for the impurity elements 103. Moreover, the reactive oxygen can transmit through a limited thickness of the initial film layer 102, and a higher gas flow does not improve the ultraviolet transmittance of the initial film layer 102 at a bottom; therefore, an excessive gas flow of the reactive oxygen treatment 104 may only lead to an increase in process costs.

The reactive oxygen treatment 104 can increase the ultraviolet transmittance of the initial film layer 102, so that the initial film layer 102 already has a high ultraviolet transmittance during subsequent ultraviolet irradiation treatment. Therefore, most of the initial film layer 102 may be irradiated by ultraviolet light, and most of the impurity elements 103 obtain a lot of energy through the ultraviolet irradiation treatment.

The reactive oxygen treatment 104 also enables the impurity elements 103 in the initial film layer 102 at a top to obtain energy. Such impurity elements 103 obtaining energy during the reactive oxygen treatment 104 can meet an energy requirement of escaping from the initial film layer only by obtaining a small amount of energy during subsequent ultraviolet irradiation treatment and thermal treatment. It may be understood that, at a stage of the reactive oxygen treatment, a small amount of impurity elements can obtain sufficient energy and escape from the initial film layer 102.

In the present embodiment, the reactive oxygen treatment 104 has a process duration of 10 s to 180 s, which may specifically be 20 s, 50 s or 120 s.

When the process duration of the reactive oxygen treatment 104 is too short, an ultraviolet transmittance of a part of the initial film layer 102 that can be transmitted through by reactive oxygen is not completely increased by the reactive oxygen. The reactive oxygen treatment 104 is intended mainly to increase the ultraviolet transmittance of the initial film layer 102 instead of providing energy for the impurity elements 103. Moreover, the reactive oxygen can transmit through a limited thickness of the initial film layer 102, and a longer process duration does not improve the ultraviolet transmittance of the initial film layer 102 at the bottom; therefore, a too long process duration of the reactive oxygen treatment 104 may only lead to an increase in process costs.

A process temperature of the reactive oxygen treatment 104 ranges from 5° C. to 150° C., which may specifically be 40° C., 80° C. or 120° C.

The process temperature of the reactive oxygen treatment 104 should not be too high. If the process temperature of the reactive oxygen treatment is too high, the initial film layer may form a solid film layer during the reactive oxygen treatment. However, the impurity elements in the initial film layer do not escape from the initial film layer in this case due to insufficient energy. When the initial film layer is converted into the solid film layer, the impurity elements remain in the film layer, which is not conducive to the formation of a high-quality film layer.

Referring to FIG. 5, ultraviolet irradiation treatment 105 is performed on the initial film layer 102.

The ultraviolet irradiation treatment 105 provides energy for most of the impurity elements 103 in the initial film layer 102, so that the impurity elements 103 can escape from the initial film layer 102 only by being provided with little energy during the subsequent thermal treatment. The impurity elements 103 escaping from the initial film layer 102 only with little energy provided by the thermal treatment means that all the impurity elements 103 can escape from the initial film layer 102 within a short time of the thermal treatment. The thermal treatment is intended mainly to improve density and hardness of the initial film layer 102 and convert it into a solid film layer 106, which requires more energy and takes a longer time to perform the thermal treatment. Therefore, during a time period of escape of the impurity elements, the initial film layer 102 cannot be converted into the solid film layer.

It may be understood that some of the impurity elements 103 obtain enough energy to escape from the initial film layer 102 when the ultraviolet irradiation treatment 105 is performed, and some of the impurity elements 103 escape from the initial film layer during the ultraviolet irradiation treatment 105.

A process temperature of the ultraviolet irradiation treatment 105 ranges from 5° C. to 150° C., which may specifically be 20° C., 80° C. or 120° C.

The process temperature of the ultraviolet irradiation treatment 105 should not be too high. If the process temperature of the ultraviolet irradiation treatment is too high, the initial film layer may form a solid film layer during the ultraviolet irradiation treatment. However, the impurity elements in the initial film layer do not escape from the initial film layer in this case due to insufficient energy. When the initial film layer is converted into the solid film layer, the impurity elements remain in the film layer, which is not conducive to the formation of a high-quality film layer.

In the present embodiment, the ultraviolet irradiation treatment 105 has a process duration of 120 s to 360 s, which may specifically be 200 s, 250 s or 300 s.

A too short process duration of the ultraviolet irradiation treatment 105 easily results in that some impurity elements in the initial film layer 102 are not irradiated and do not obtain enough energy. A too long process duration of the ultraviolet irradiation treatment 105 easily damages a chemical bond between other elements in the initial film layer and affects chemical properties of the initial film layer.

Ultraviolet light used for the ultraviolet irradiation treatment 105 has a wavelength range of 50 nm to 300 nm, which may specifically be 100 nm, 150 nm or 200 nm.

In the present embodiment, a ratio of time of the reactive oxygen treatment 104 (refer to FIG. 4) to time of the ultraviolet irradiation treatment 105 is 1:3 to 1:10, which may specifically be 1:4, 1:6 or 1:8.

A reason for adopting such a time ratio for the reactive oxygen treatment 104 and the ultraviolet irradiation treatment 105 is that the reactive oxygen treatment 104 is intended mainly to improve the ultraviolet transmittance of the initial film layer 102, so the reactive oxygen treatment is not required to be performed for a too long time; however, the ultraviolet irradiation treatment 105 is intended to provide a large amount of energy for the impurity elements, so the ultraviolet irradiation treatment is required to be performed for a longer time.

In other embodiments, after the initial film layer is formed, the ultraviolet irradiation treatment may be performed, followed by the reactive oxygen treatment. The reactive oxygen treatment is intended to provide energy for the impurity elements in the initial film layer, and the ultraviolet irradiation treatment has a same effect as the reactive oxygen treatment.

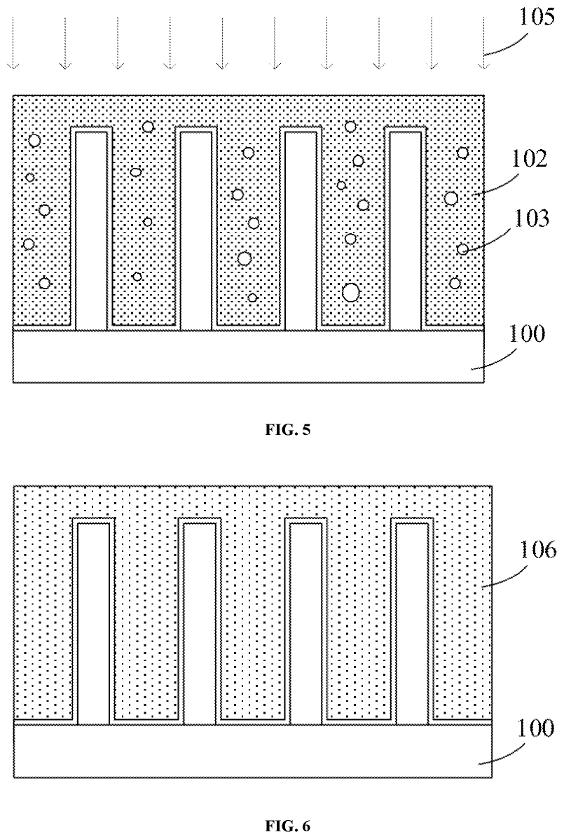

Referring to FIG. 6, in the present embodiment, thermal treatment is performed on the initial film layer 102 (refer to FIG. 5) in an aerobic environment, the impurity elements 103 (refer to FIG. 5) are removed, and the initial film layer 102 is converted into a solid film layer 106.

The impurity elements 103 obtain a large amount of energy during the ultraviolet irradiation treatment 105 (refer to FIG. 5), during the thermal treatment, the energy obtained by the impurity elements 103 may soon reach a degree that they can escape from the initial film layer 102. When the impurity elements 103 escape from the initial film layer 102, a top of the initial film layer 102 is not enough to be converted into the solid film layer 106.

The film layer 106 may be made of silicon oxide. Since the thermal treatment is performed in the aerobic environment, the silicon nitrogen hydroxide layer may react with oxygen to form silicon oxide. The silicon oxide is an insulation material and is configured to isolate the gates in the semiconductor structure from each other.

The thermal treatment is at a process temperature of 500° C. to 1000° C., which may specifically be 600° C., 750° C. or 900° C.

The higher temperature of the thermal treatment is to allow the silicon nitrogen hydroxide layer to react fully with oxygen to form a silicon oxide layer, and at the same time to convert the fluidic initial film layer 102 into the solid film layer 106, which requires a lot of energy.

In the present embodiment, the deposition of the initial film layer 102, the reactive oxygen treatment 104 (refer to FIG. 4), the ultraviolet irradiation treatment 105 and the thermal treatment are performed in a same reaction chamber. In this way, during the formation of the film layer 106, all processes are performed in the same reaction chamber without changing the reaction chamber, which simplifies process steps and reduces contamination of the reaction chamber possibly caused by the change of the chamber at the same time.

In the semiconductor structure formation method according to the embodiments of the present application, after the initial film layer containing impurity elements is formed, firstly, reactive oxygen treatment is performed on the initial film layer, which may improve an ultraviolet transmittance of the initial film layer; then, ultraviolet irradiation treatment is performed. Due to a high ultraviolet transmittance of the initial film layer, each part of the initial film layer can be irradiated by ultraviolet light, and all the impurity elements obtain a lot of energy through the ultraviolet irradiation treatment. In this way, during the thermal treatment, the impurity elements can escape from the initial film layer only with a small amount of energy. It takes only a small amount of time for the impurity elements to obtain a small amount of energy, ensuring that the impurity elements escape from the initial film layer before the initial film layer at the top is cured, so as to reduce a content of the impurity elements in a film layer finally formed and improve the quality of the film layer of the semiconductor structure.

A second embodiment of the present application provides a semiconductor structure formed based on the above semiconductor structure formation method. The semiconductor structure according to the second embodiment of the present application is described in detail below with reference to the accompanying drawings.

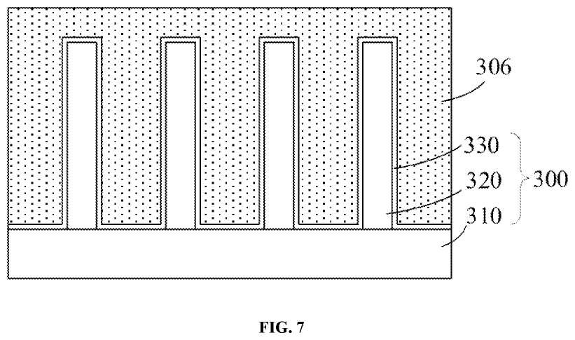

FIG. 7 is a schematic structural diagram of a semiconductor structure according to a second embodiment of the present application.

Referring to FIG. 7, the semiconductor structure according to the present embodiment includes: a base 300, the base 300 being provided with a trench (not marked); and a film layer 306 filling up the trench, the film layer 306 being formed according to the above semiconductor structure formation method.

The base 300 is of a multilayer structure and includes: a substrate 310, a gate 320 and a diffusion barrier layer 330.

The substrate 310 may be made of sapphire, silicon, silicon carbide, gallium arsenide, aluminum nitride, zinc oxide or the like. In the present embodiment, the substrate 310 is made of a silicon material.

Discrete gates 320 are formed on a surface of the substrate 310. The gate 320 serves as a wordline structure of the semiconductor structure. The gate 320 is made of tungsten. In other embodiments, the gate may also be made of copper, aluminum, gold, silver or the like.

The diffusion barrier layer 330 is formed on surfaces of the substrate 310 and the gate 320. The diffusion barrier layer 330 may prevent diffusion of metal particles in the gate 320.

The diffusion barrier layer 330 may be of a monolayer structure or a multilayer structure. The diffusion barrier layer 330 may be made of a nitride or an oxide, which may specifically be tantalum nitride or titanium nitride.

In the present embodiment, the film layer 306 is an insulation layer and is configured to isolate the gates in the semiconductor structure from each other. The film layer 306 may be made of silicon oxide.

The film layer in the semiconductor structure according to the present embodiment is a film layer formed according to the above semiconductor structure formation method. Impurity elements in the formed film layer have a low content, which improves the quality of the film layer of the semiconductor structure.

Those of ordinary skill in the art may understand that the above implementations are specific embodiments for implementing the present application. However, in practical applications, various changes in forms and details may be made thereto without departing from the spirit and scope of the present application. Any person skilled in the art can make respective changes and modifications without departing from the spirit and scope of the present application. Therefore, the protection scope of the present application should be subject to the scope defined by the claims.

What is claimed is:

1. A semiconductor structure formation method, comprising:
providing a base and a trench located in the base, and depositing a fluidic initial film layer in the trench, impurity elements being present in the initial film layer;
performing reactive oxygen treatment on the initial film layer;
performing ultraviolet irradiation treatment on the initial film layer; and
performing thermal treatment on the initial film layer in an aerobic environment, removing the impurity elements, and converting the initial film layer into a solid film layer.

2. The semiconductor structure formation method according to claim 1, wherein a process temperature of the reactive oxygen treatment ranges from 5° C. to 150° C.

3. The semiconductor structure formation method according to claim 1, wherein a process temperature of the ultraviolet irradiation treatment ranges from 5° C. to 150° C.

4. The semiconductor structure formation method according to claim 1, wherein a ratio of time of the reactive oxygen treatment to time of the ultraviolet irradiation treatment is 1:3 to 1:10.

5. The semiconductor structure formation method according to claim 4, wherein the ultraviolet irradiation treatment has a process duration of 120 s to 360 s.

6. The semiconductor structure formation method according to claim 4, wherein process parameters of the reactive oxygen treatment comprise a process duration of 10 s to 180 s.

7. The semiconductor structure formation method according to claim 1, wherein the reactive oxygen treatment involves providing peroxide, superoxide, or ozonide for the initial film layer.

8. The semiconductor structure formation method according to claim 7, wherein a gas flow of the peroxide, the superoxide, or the ozonide is 1000 sccm to 20000 sccm.

9. The semiconductor structure formation method according to claim 7, wherein the peroxide, the superoxide, or the ozonide comprises superoxide anions, hydrogen peroxide, hydroxyl radicals, ozone, or singlet oxygen.

10. The semiconductor structure formation method according to claim 1, wherein the trench has an aspect ratio of 5:1 to 25:1.

11. The semiconductor structure formation method according to claim 1, wherein the initial film layer is made of silicon nitrogen hydroxide, the film layer is made of silicon oxide, and the thermal treatment is at a process temperature of 500° C. to 1000° C.

12. The semiconductor structure formation method according to claim 1, wherein the deposition of the initial film layer, the reactive oxygen treatment, the ultraviolet irradiation treatment and the thermal treatment are performed in a same reaction chamber.

13. A semiconductor structure, comprising:
a base, the base being provided with a trench; and
a film layer filling up the trench, the film layer being formed with the semiconductor structure formation method according to claim 1.

14. The semiconductor structure according to claim 13, wherein the base is of a multilayer structure and comprises a substrate, a gate and a diffusion barrier layer.

15. The semiconductor structure according to claim 13, wherein the film layer is an insulation layer, and the film layer is made of silicon oxide.

16. A semiconductor structure comprising a film layer formed with the method according to claim 2, the semiconductor structure further comprising:
a base provided with a trench;
wherein the film layer fills up the trench.

17. A semiconductor structure comprising a film layer formed with the method according to claim 3, the semiconductor structure further comprising:
a base provided with a trench;
wherein the film layer fills up the trench.

18. A semiconductor structure comprising a film layer formed with the method according to claim 7, the semiconductor structure further comprising:
a base provided with a trench;
wherein the film layer fills up the trench.

19. A semiconductor structure comprising a film layer formed with the method according to claim 10, the semiconductor structure further comprising:
a base provided with a trench;
wherein the film layer fills up the trench.

20. A semiconductor structure comprising a film layer formed with the method according to claim 11, the semiconductor structure further comprising:
a base provided with a trench;
wherein the film layer fills up the trench.
